(19) United States
(12) Patent Application Publication
(10) Pub. No.: US 2019/0198313 A1
(43) Pub. Date: Jun. 27, 2019

(54) Flexible Single-Crystal Semiconductor Heterostructures and Methods of Making Thereof

(71) Applicant: University of Houston System, Houston, TX (US)

(72) Inventors: Jae-Hyun Ryou, Houston, TX (US); Shahab Shervin, Houston, TX (US)

(73) Assignee: University of Houston System, Houston, TX (US)

(21) Appl. No.: 16/331,490

(22) PCT Filed: Sep. 8, 2017
(86) PCT No.: PCT/US2017/050844

§ 371 Date: Mar. 7, 2019

Related U.S. Application Data
(60) Provisional application No. 62/393,165, filed on Sep. 12, 2016.

(51) Int. Cl. H01L 21/02; H01L 29/20; H01L 31/0304; H01L 33/32; H01L 33/00; H01L 31/18; C30B 25/18; C30B 29/40; C30B 29/02; C30B 29/68

(52) U.S. Cl. CPC H01L 21/0262; C30B 29/68; H01L 21/02381; H01L 21/02425; H01L 21/02439; H01L 21/02444; H01L 21/02458; H01L 21/02505; H01L 21/0254; H01L 29/2003; H01L 31/03044; H01L 33/32; H01L 33/007; H01L 31/1852; H01L 31/1856; C30B 25/183; C30B 29/403; C30B 29/02; C30B 29/406; H01L 21/02433

(57) ABSTRACT

Discussed herein are systems and methods for fabrication of flexible electronic structures via direct growth of two-dimensional materials on metal foil and the direct growth of 2D materials on any substrate including polycrystalline, single crystal, and amorphous substrates, that may employ an adhesion layer of, for example, a Cu or Ni film, formed directly on the substrate prior to formation of subsequent layers.

### CROSS-REFERENCE TO RELATED APPLICATIONS

This application is a 35 U.S.C. § 371 national stage application of PCT/US2017/050844 filed Sep. 8, 2017, which claims priority to U.S. Application No. 62/393,165 titled, “Flexible Single-Crystal Semiconductor Heterostructures by Direct Growth and Methods of Making Thereof,” filed Sep. 12, 2016, each of which is incorporated by reference herein in their entirety for all purposes.

### STATEMENT REGARDING FEDERALLY SPONSORED RESEARCH OR DEVELOPMENT

None.

### BACKGROUND

### Background of the Technology

Semiconductors, including III-V semiconductor materials, are considered as an alternative to Si-based semiconductors. Recently, the semiconductor technology further relies on the newly-developed III-V materials driven by the demands for unique and advanced properties in the new applications. However, the materials and device technology in such applications face both technical and economic challenges for the next-generation applications. The efficiencies and performances need to be further improved while the product prices need to be reduced. In addition, the application locations and functionality of the semiconductor devices are to be expanded. To address the challenges in the next-generation high-efficiency, flexible, and multifunctional electronic and photonic devices and to reduce manufacturing costs, a whole new technology platform is needed, instead of incremental improvement of characteristics at marginally reduced costs using the current platform. The development can begin from the substrate of the semiconductor materials structures, which is one of the most dominant limiting factors in terms of device mechanical flexibility and manufacturing costs.

### BRIEF SUMMARY OF THE DISCLOSURE

In an embodiment, a method of fabricating a semiconductor device comprising: directly forming, via chemical vapor deposition, a 2D material on a substrate, wherein the substrate comprises Si (100), a metallic foil, or an inorganic flexible substrate, and the 2D material comprises black phosphorous, hexagonal boron nitride (BN), or graphene. In an embodiment, the method further comprises directly forming a c-axis AlN layer on the 2D material layer, wherein the AlN layer comprises the same crystallographic structure as the 2D material layer, directly forming a GaN layer on the AlN layer via chemical vapor deposition (CVD). In an embodiment, the method further comprises forming the GaN layer to comprise a wurtzite structure, wherein the AlN layer does not comprise a wurtzite structure.

In an embodiment, a method of fabricating a semiconductor structure comprising: directly forming a catalyst layer in contact with a substrate; forming a 2D material layer on the catalyst layer; forming an AlN layer on the 2D material layer; forming a buffer layer on the AlN layer; and forming at least one semiconductor layer on the buffer layer. In one example, the at least one semiconductor layer comprises GaN, InₓGa₁₋ₓN, or InₓAl_{y}Ga_{1-x-y}N, and 0≤x≤1 for AlₓGa₁₋ₓN, wherein 0≤x≤1 for InₓGa₁₋ₓN, wherein 0≤x≤1 for InₓAl_{y}Ga_{1-x-y}N, and wherein for InₓAl_{y}Ga_{1-x-y}N. In an embodiment, the method further comprises forming an adhesion layer on the substrate prior to forming the catalyst layer, wherein the adhesion layer comprises titanium (Ti), chromium (Cr), or nickel (Ni), or combinations thereof and the catalyst layer is formed by electroplating, physical vapor deposition (PVD), or electron beam (e-beam) evaporation

In an embodiment, a semiconductor structure comprising: a substrate; a layer of 2D material formed in contact with the substrate; a first buffer layer formed on the 2D material layer; a second buffer layer formed on the first buffer layer; and a plurality of semiconductor layers grown epitaxially on the second buffer layer. In an embodiment, the structure further comprises a catalyst layer formed on the substrate layer, wherein the 2D material layer is formed directly on the catalyst layer and the thickness of the catalyst layer is from about 1 nm to about 1 mm and an adhesion layer formed between the substrate layer and the catalyst layer. In an embodiment, the adhesion layer comprises titanium (Ti), chromium (Cr), or nickel (Ni), or combinations thereof and has a thickness of 0.1 nm-1 μm. In one example, the first buffer layer comprises AlN, the second buffer layer comprises GaN, and substrate comprises one of a polycrystalline structure; a single-crystalline structure; and an amorphous structure. Further in this embodiment, the first buffer layer comprises a substantially similar crystallographic structure to a crystallographic structure of the 2D material layer and the first buffer layer comprises a different crystallographic structure than the second buffer layer.

### BRIEF DESCRIPTION OF THE DRAWINGS

For a detailed description of the exemplary embodiments disclosed herein, reference will now be made to the accompanying drawings in which:

FIG. 1 is a schematic cross section of AlN disposed on a graphene layer on a Cu foil according to certain embodiments of the present disclosure.

FIGS. 2A-2C are x-ray diffraction (XRD) results including a 2theta-omega scan (2A), a rocking curve (2B), and a pole FIG. 2C) for AlN deposited on a Cu foil according to certain embodiments of the present disclosure.

FIGS. 3A and 3B illustrate a crystal structure and axis of GaN, AlN, and AlₓIn_{y}Ga_{1-x-y}N materials having wurtzite structure.

FIGS. 4A and B are scanning electron microscopy (SEM) images of surface morphology of an AlN layer deposited on Cu foil (4A) with a scale bar of 500 μm; and a graphene layer deposited before the AlN layer deposition with a scale bar of 10 μm (4B) according to certain embodiments of the present disclosure.

FIG. 5 is an atomic force microscopy (AFM) image of AlN layer on Cu foil with graphene intermediate layer according to certain embodiments of the present disclosure.

FIG. 6. Illustrates a structure of GaN grown by MOCVD on AlN deposited on a graphene intermediate layer grown on a metal tape using CVD method according to certain embodiments of the present disclosure.

FIG. 7 is an XRD 2theta-omega scan for the MOCVD grown GaN using sputtered AlN as buffer layer on Cu foil with graphene intermediate layer according to certain embodiments of the present disclosure.

FIGS. 8A and 8B are XRD analyses including a phi-rotational scan on GaN film grown according to certain embodiments of the present disclosure on AlN buffer layer with using graphene as intermediate layer on top of Cu foil for the (102) plane of the grown GaN (8A) and a rocking curve for the (002) plane of MOCVD grown GaN (8B).

FIG. 9 illustrates a semiconductor structure of a substrate, adhesion layer, catalyst film, 2D material layer, an AlN layer, a GaN buffer layer, and an AlₓIn_{y}Ga_{1-x-y}N layer according to certain embodiments of the present disclosure.

FIGS. 10A and 10B are SEM images of surface morphology of graphene layer on 300 nm of thermally grown SiO₂ on Si (100) wafer with a scale bar of 10 μm (10A) and with a scale bar of 2 μm (10B) fabricated according to certain embodiments of the present disclosure.

FIG. 10C is a Raman spectra for graphene layer fabricated according to certain embodiments of the present disclosure.

FIGS. 11A and 11B are SEM images of surface morphology of a graphene layer flexible YSZ tape according to certain embodiments of the present disclosure with a scale bar of 10 μm (11A) and with a scale bar of 2 μm (11B).

FIG. 11C is a Raman spectra for the graphene layer of the flexible YSZ tape.

FIG. 12 is a Raman spectra for a graphene layer on a YSZ flexible substrate with 100 nm of deposited catalyst Ni film.

### DETAILED DESCRIPTION OF THE DISCLOSED EXEMPLARY EMBODIMENTS

The following discussion is directed to various exemplary embodiments. However, one of ordinary skill in the art will understand that the examples disclosed herein have broad application, and that the discussion of any embodiment is meant only to be exemplary of that embodiment, and not intended to suggest that the scope of the disclosure, including the claims, is limited to that embodiment.

The drawing figures are not necessarily to scale. Certain features and components herein may be shown exaggerated in scale or in somewhat schematic form and some details of conventional elements may not be shown in interest of clarity and conciseness.

In the following discussion and in the claims, the terms “including” and “comprising” are used in an open-ended fashion, and thus should be interpreted to mean “including, but not limited to . . . .”

This application incorporates by reference in its entirety PCT Patent Application PCT/US16/26707, “Externally-Strain-Engineered Semiconductor Photonic and Electronic Devices and Assemblies and Methods of Making Thereof,” filed Apr. 8, 2016.

Discussed herein are methods for the direct growth of nearly-single-crystalline III-nitride (III-N) semiconductor materials on amorphous-, polycrystalline-, and other foreign-single-crystalline substrates including flexible substrates. “Nearly” single crystalline material may have a dislocation density of about 10⁹ cm² whereas as single crystalline material has a dislocation density of less than about 10⁸ cm². As used herein, a “flexible” substrate or device comprises a substrate or device that is able, while in a first state to be put under tension, compression, torsion, and other strain in one or more directions for a sustained period of time or for a predetermined number of cycles of application and removal of force in a second, force-application state. Once the period of time or number of cycles (or a combination thereof) is reached, the flexible substrate or device returns to its first state. The flexible inorganic photonic and electronic devices fabricated using the systems and methods discussed herein can be used for next-generation solid-state lighting, electronic, electro-mechanic, and photonic applications. Furthermore, embodiments of the systems, structures and methods discussed herein are applicable for monolithic integration of well-matured Si-based devices and emerging III-N-based devices.

Graphene and other 2-dimensional materials may be grown directly on different substrates by inserting a catalyst film. As discussed herein, the “direct growth” or formation of a first component on or partially on a second component (e.g., layers) is used to indicate that there is no transfer process involved in the fabrication of these devices, the layers are formed directly on other layers, in place and in order, in contrast with devices and methods of fabrication of those devices where various layers are formed and then transferred to the semiconductor structure.

These 2D materials may thus serve as an intermediate layer for III-N material deposition to achieve the flexible material heterostructure with single crystalline properties in active device region. In particular, the present disclosure comprises: (1) systems, structures and methods for the direct growth of graphene or other 2-dimensional material, such as hexagonal BN on various different types substrates via a chemical vapor deposition (CVD) method to serve as an intermediate layer for the next III-N layers' growth; (2) the deposition of III-N layers with preferred crystalline axes (nearly-single-crystalline device-quality layers) on Si substrates with a native oxide on grown on top; (3) a method of monolithic integration of wide-band gap III-N devices with Si-based devices is proposed; (4) the direct formation (deposition) of industrially-viable, high-quality III-N layers on the flexible substrate by direct growth is suggested; (5) the fabrication of III-N-based devices on flexible substrates. The embodiments of direct deposition methods and resultant structures discussed herein for high-quality flexible materials and devices is aimed to provide high-performance flexible devices with high durability, roll-to-roll continuous fabrication, low production costs, and high materials quality. “Direct” deposition comprises the formation of a second layer in contact, which may or may not include patterning, etching, and other steps. Current challenges associated with the manufacture of expensive fragile substrates may be addressed through the systems, structures and methods herein. As used herein, a “high-quality” III-N layers are those layers associated with a threading dislocation density from about 10³ to 10¹¹ per/cm².

In various examples, III-V semiconductor materials may be employed as an alternative to Si-based semiconductors. Among III-V materials, III-nitride (III-N) materials have commercially viable electronic and photonic properties. III-N materials, including gallium nitride (GaN) and its related materials such as aluminum gallium nitride (AlₓGa₁₋ₓN, 0≤x≤1), indium gallium nitride (InₓGa₁₋ₓN, 0≤x≤1) and indium aluminum gallium nitride (InₓAl_{y}Ga_{1-x-y}N, 0≤x≤1 and) with wurtzite crystal structures (based on hexagonal lattice), may be employed for solid-state lighting (SSL) and high-power switching- and conversion-applications.

Among different deposition and epitaxial growth techniques of III-N semiconductor materials, metalorganic chemical vapor deposition (MOCDV) method may be used due to its high deposition rate, high throughput, growth parameter controllability, and superb material quality of the products. For the epitaxial growth of MOCVD of III-N materials, single-crystalline sapphire, silicon carbide (SiC), Si (111) wafers are the most widely used substrates. Some limiting factors of the single-crystalline substrates, including high cost, limited size, and non-mechanical flexibility have motivated the search for reliable substrates to use for fabrication of semiconductors.

The methods, structures and systems discussed herein are at least: (1) low cost in substrate materials and material processing and (2) have a comparable or superior quality of III-N material structures as compared to those formed on single-crystalline substrates.

For low cost in substrate materials, polycrystalline or amorphous materials are generally less expensive than single-crystalline materials. Also, scaling-up of the size is easier for polycrystalline or amorphous materials, because precisely controlled bulk solidification process is omitted. In addition, mechanical flexibility can be achieved from substrates in the form of tape/foil instead of wafers. The tape substrate enables the continuous deposition of materials by roll-to-roll growth, which is expected to offer low production cost in material deposition process. Inexpensive substrates such as metal, ceramic, or glass tapes with polycrystalline or amorphous structures may be employed to reduce the substrate cost, low material processing cost, and mechanical flexibility. The substrates discussed herein provide the high structural quality of the III-N materials comparable to the single-crystalline substrates. Discussed herein is a technique to grow buffer layers on the substrates to obtain device-quality III-N materials on low-cost non-single-crystalline substrates. Developing desired buffer layers with low-cost method and implementing intermediate layer on the flexible substrates will result in a novel platform for MOCVD growth of III-N materials. Using the systems and methods discussed herein, there is improved affordability and functionality of III-N-based devices with high quality of the epitaxial layers.

In an embodiment, III-N-based devices are integrated with Si technology on the same (shared) substrate. The Si technology uses Si (100) wafers (single-crystalline Si wafer with cubic atomic configuration on the plane of surface), not Si (111) wafers which may be used in GaN epitaxial growth. The epitaxial growth of III-N wurtzite on Si (100) wafers is technically challenging due to dissimilarity in their crystal structures and atomic configurations. Obtaining device-quality III-N material on Si (100) enables the expanded monolithic integration of Si technology.

Direct Growth of 2D Structures on a Substrate

Graphene and similar materials with honeycomb atomic configurations are 2-dimensionally-structured materials may experience weak atomic bonding to underlying material and strong in-plane atomic bonding. Graphene has a honeycomb structure and is used herein as a template for the epitaxial growth of GaN with a hexagonal wurtzite structure. In contrast to currently employed methods where graphene is grown on a metal foil and transferred to another substrate for GaN growth, the systems and methods used herein employ graphene grown directly on, for example, single crystalline, polycrystalline, and amorphous substrates, as well as on adhesion layers and catalyst layers. Thus, embodiments of methods discussed herein are directed towards the growth of III-N materials on graphene, in contrast to currently employed transfer methods. To achieve the high-quality epitaxially grown III-N materials on different amorphous and polycrystalline flexible substrates, a multi-step direct deposition method (transfer-free) is discussed.

In some embodiments, for the growth of graphene, catalyst materials may be employed. In some examples, Cu and Ni are used for growth of graphene in the form of either thin films or foils that may range in thickness from about 1 nm to about 1 mm thick. The deposition of a thin film catalyst material such as Cu and Ni on the desired substrate may enable the direct growth of graphene via chemical vapor deposition (CVD) on the thin film catalyst. Hence, by taking advantage of the graphene or other 2-d material structure, high-quality III-N materials are achievable independent of the choice of the substrate since the semiconductor material is not formed directly on the substrate. That is, there is no transfer process of the semiconductor involved in the formation of the semiconductor devices discussed herein. Rather, the graphene transferring step is omitted, which simplifies the process, reduces manufacturing costs, and avoids the technical challenges associated with organic material residuals.

The systems and methods herein are aimed at producing device-quality GaN on any given inorganic rigid or flexible substrate regardless of its amorphous, polycrystalline, or single-crystalline structure. The systems and methods discussed herein may extend to applications for devices such as lasers, LEDs including deep ultra violet (DUV) LED and visible LEDs, photodetectors (PDs), and high electron mobility transistors (HEMT). Furthermore, the described growth process is applicable to Si wafer especially Si (100), the most widely used in silicon industry, which deliveries III-N-based device integration with Si-based devices. Integrated circuit (IC) technology will take the advantage of integrating devices such as HEMTs, PDs, LEDs, etc. with available Si-based devices on the same Si substrate during the fabrication process.

Various embodiments discussed herein are associated with (a) The growth of single-crystal semiconductor materials such as III-N materials on inorganic flexible substrates; (b) delivering roll-to-roll continues growth of high quality III-N materials; (c) Reducing fabrication and production cost; (d) High-performance flexible and bendable electronic and photonic devices with broad applications; (e) Single-crystal III-N materials on both amorphous or polycrystalline substrates; (f) Integrating Si-based semiconductor technology with III-N materials industry by suggesting the multi-step deposition methods which are applicable for the same substrate; (g) High-performance electronic and photonic devices with versatile applications; and (h) Extension of multifunctioning devices with relying on simple growth method.

Design and Process: Methods Expanding Flexible Device- and Si-Based-Technology

Discussed herein are methods of growing single-crystalline GaN on substrates by direct deposition of multiple layers to grow single-crystalline GaN. The substrates used for the embodiments discussed herein may be those with amorphous structures such as glass or Si wafer with native oxide (SiO₂); or, polycrystalline structures such as ceramics or metals. This method is applicable for both rigid and flexible substrates with either polycrystalline or amorphous structure.

In an embodiment, AlN may be employed as the buffer layer when GaN is grown, owing to its similar material system to GaN. A sputtering process is one the most convenient deposition methods for the AlN deposition as a buffer layer for GaN growth, as it is a low-cost and easily-accessible method comparing to other deposition methods. It is to be understood that the GaN layer may also serve as a buffer layer in various embodiments, and that the use of the term “buffer” may be used to describe a variety of layers in various layer configurations where layer Y is deposited on layer X prior to the deposition of layer Z. In that high level example, layer Y would be the buffer layer, but layer Z may also be a buffer layer is a subsequent layer Q is deposited on layer Y. In some embodiments discussed herein, the methods and structures may also employ directly grown graphene as an intermediate layer for AlN layer.

In various embodiments, different processes may be employed for graphene growth: (1) using direct growth on metal foil (copper (Cu), nickel (Ni), etc.); and (2) growth on any substrate (polycrystalline, single crystal, and amorphous) with an adhesion layer of, for example, a Cu or Ni film. These different platforms may be employed for suggests various types of applications for the next-generation electronic and photonic devices that may include flexible devices.

### Example 1: Direct Growth of AlN Layer on Graphene

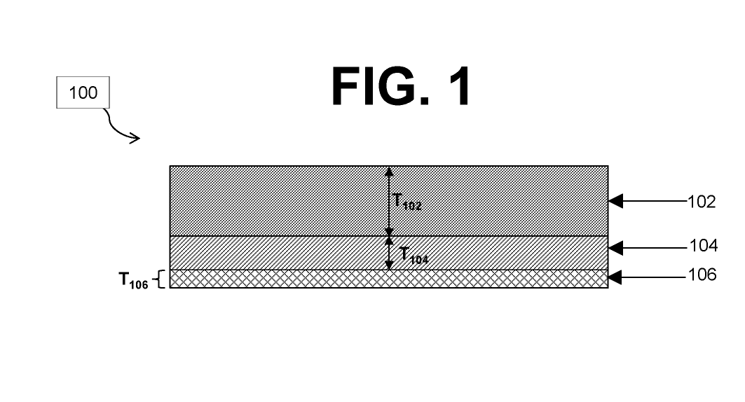

FIG. 1 is an illustration of a schematic cross section of a structure according to certain embodiments of the present disclosure. FIG. 1 shows a cross-section of a structure 100 formed by the direct growth of III-N materials such as GaN or AlN (102) as a buffer layer on mechanically soft and flexible foil with variety of thicknesses ranging from 1 μm up to tens of millimeters.

The structure in FIG. 1 comprises a high-quality c-axis oriented AlN layer 102 directly deposited on the graphene layer 104. The graphene layer 104, prior to the deposition of the AlN layer 102, is grown on a polycrystalline substrate 106. In one example, this may be a metallic foil such as a Cu foil substrate 106. In this example, there is no additional substrate is formed in contact with the substrate 106 and this may be referred to as a “stand-alone” embodiment. In one example, the graphene layer 104 is grown directly via CVD (“direct CVD”) and not grown separately and transferred. The direct growth of the graphene layer 104 on the Cu foil 106 can be delivered by optimizing the CVD parameters on Cu foil. In one example, a high-quality AlN layer 102 is formed on the graphene 104 by DC magnetron sputtering using Al target with reaction gas of nitrogen with optimized deposition parameters, in some embodiments, the sputtering may occur at room temperature, and in other embodiments it may be performed at temperatures up to 1300° C. Thus, high-quality AlN 102 with a c-axis preferred orientation is formed on the flexible-polycrystalline Cu foil 106 via the graphene layer 104 that may be referred to as a buffer layer 104. The Cu foil 106 is one example of an inorganic substrate that may be compatible with directly CVD grown graphene 104 or other two-dimensional (2D) materials such as black phosphorous and hexagonal boron nitride (BN). The layers of AlN 102, graphene 104, and the Cu foil 106 are illustrated in FIG. 1 as being of various relative thicknesses, T₁₀₂, T₁₀₄, and T₁₀₆, respectively. These thicknesses may vary in individual measurement and with respect to the thickness ratio of the individual layers depending upon the embodiment. In one example, the thickness T₁₀₂ of the AlN layer 102 may be from about 0.1 nm to about less than 100 micrometers, the thickness T₁₀₆ may be from about 1 nm to about 1 mm, and the thickness of the graphene layer 604 may be from about 1 monolayer to about 10 nm.

The example in FIG. 1 may be fabricated with a Cu foil 106 as the substrate, and in other embodiments, nickel (Ni) or another metallic foil may be employed. This is in contrast to conventional processes where previously-grown graphene is transferred to favored substrates by removing the Cu foil underlayer for further applications, at least because the systems and methods and structures discussed herein illustrate that graphene grown on top of Cu foil (rather than being separately formed and transferred to the Cu foil) and thus the graphene may act as an intermediate layer for the deposition of AlN and other subsequent layers.

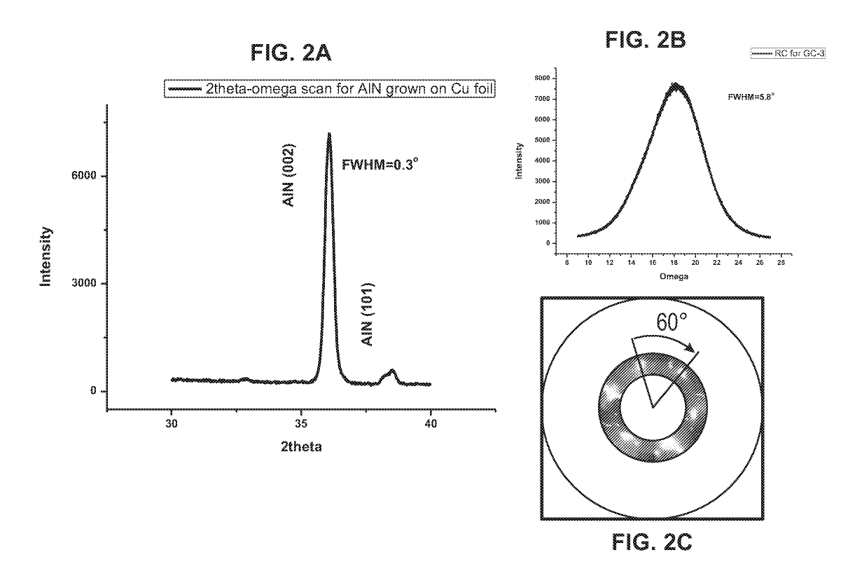

FIGS. 2A and 2B show x-ray diffraction (XRD) analysis for the structure in FIG. 1 where the AlN layer 102 is deposited on a CVD-grown intermediate graphene layer 104 on the Cu foil 106. The phase identification scan, 2theta-omega graph (FIG. 1A), and the rocking curve for AlN film 102 (FIG. 2B) were obtained from high-resolution XRD (HRXRD). The 2theta-omega curve in FIG. 2A shows AlN film is deposited with a preferred c-axis [0001] orientation. Furthermore, the rocking curve in FIG. 2B confirms small out plane tilting for AlN (0002) planes that are parallel to AlN layer 102 interface with the graphene intermediate layer 104. FIG. 2C shows a pole figure graph collected from general area detector diffraction system (GADDS) results for (1012) asymmetric plane. FIG. 2C confirms six-fold symmetry of AlN film 102 with in-plane alignment. The XRD analysis of FIGS. 2A and 2B shows that the AlN film is well aligned in both out-of-plane and in-plane directions, suggesting that the AlN crystals in the film are well aligned in biaxial directions.

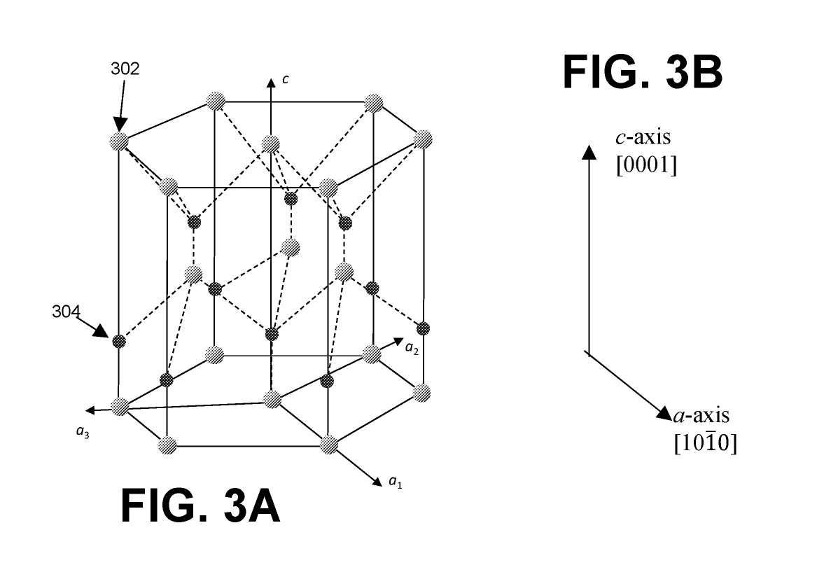

FIG. 3A shows atomic arrangement of a wurtzite unit cell and FIG. 3B illustrates crystallographic directions. In particular, these unit cells may comprise a first group element atom 302 and a second group element atom 304. The first group element 302 atom may comprise a Group II or III element such as a Ga or Zn atom, and the second group element atom 304 may comprise a Group V or VI element such as a N or O atom.

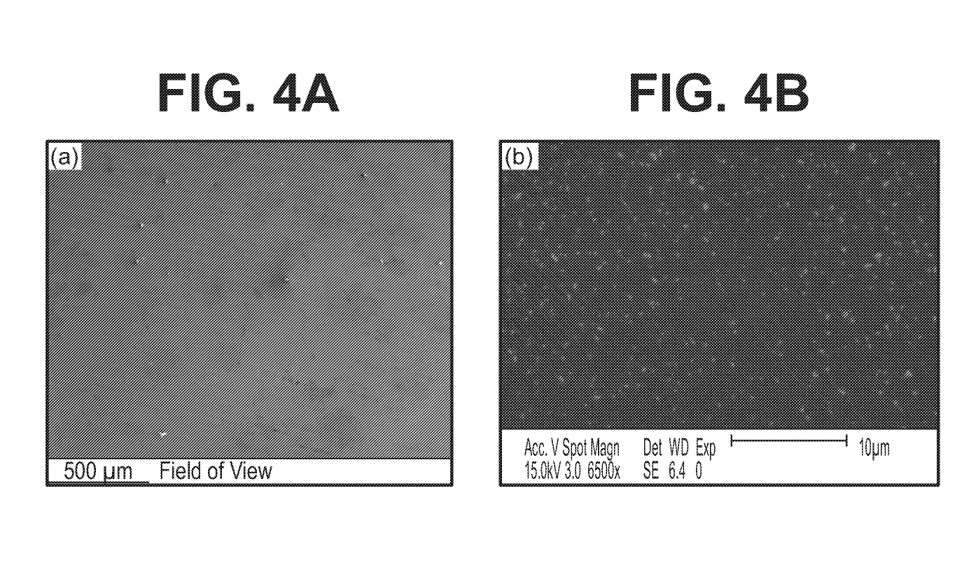

FIGS. 4A and 4B illustrate the surface morphology of deposited AlN layer (101) and the intermediate graphene layer (104) (before AlN (101) deposition) is compared by scanning electron microscopy (SEM) images.

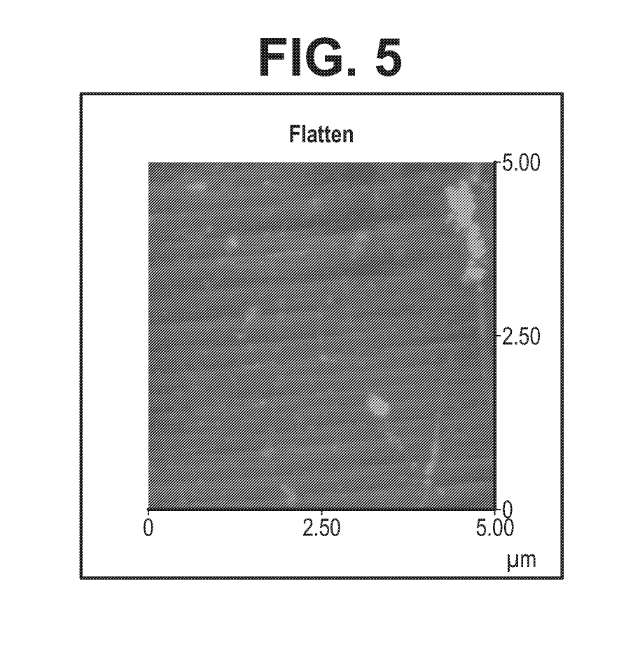

FIG. 5 is atomic force microscopy (AFM) image of the AlN film 102 grown on a graphene layer formed directly on a metallic thin film. Similar surface features can be found comparing SEM and AFM images of AlN film 102 and graphene layer 104, thus, the AlN layer 106 may follow the atomic configuration (crystallographic structure) of underlying graphene layer 104 deposited using CVD during the sputtering deposition of the AlN layer 106. The microscopic surface image of the AlN film in FIG. 5 shows a flat surface with atomic steps. In another example, the GaN layer can be grown by MOCVD method on the high oriented c-axis AlN film deposited on Cu foil with in-between graphene intermediate layer.

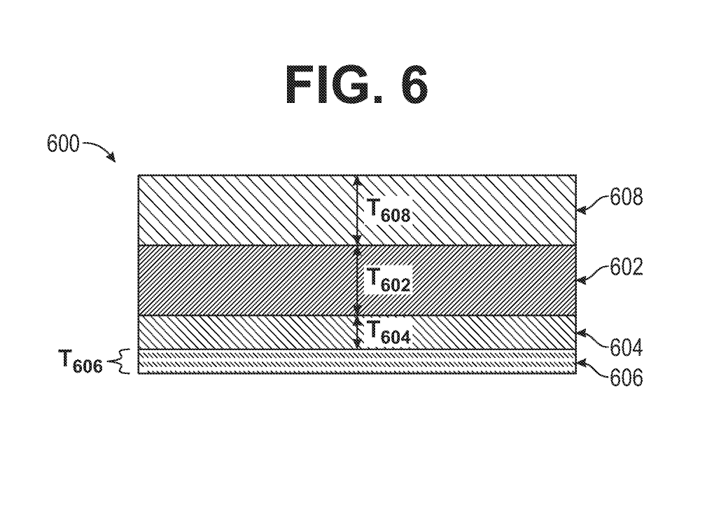

FIG. 6 illustrates a structure 600 of a semiconductor. In the structure 600, the substrate 606 may comprise a metallic foil. In an embodiment, a layer 604 of 2D material such as graphene 604 is deposited by CVD directly on the flexible substrate 606. A layer of AlN 602 is grown (deposited) directly on the graphene 604 and a layer of GaN 608 is disposed on the AlN 602. The structure 600 is characterized as discussed below. In one example, the GaN layer 608 and the AlN layer 602 comprise the same or substantially crystal structures with different atomic distances, and each layer 602, 608, has a different crystal structure than the substrate 606. In some examples, each of the layers 602 and 608 has a different crystal structure than the 2D material layer 604 but substantially similar in-plane atomic arrangements, for example, hexagonal. A “substantially similar” aspect of a layer or layer comprises a material property that is functionally the same such that the layers discussed are similar enough in property such that the layers do not delaminate during manufacture nor decrease the device life.

The layers 602, 604, 606, and 608 are shown in FIG. 6 as being of various relative thicknesses, T₆₀₂, T₆₀₄, T₆₀₆, and T₆₀₈, respectively. These thicknesses may vary in individual measurement and with respect to the thickness ratio of the individual layers depending upon the embodiment. The thickness T₆₀₂ of the AlN layer 602 may be from about 0.1 nm to about 100 micrometers, the thickness T₆₀₆ of the flexible substrate 606 may be from about 1 nm to about 1 mm, the graphene layer 604 may comprise a thickness T₆₀₄ that may range from a single monolayer 604 that may be a self-assembled monolayer 604 of about 1 Angstrom to about 10 nm, and the GaN layer 608 may comprise a thickness T₆₀₈ of the GaN layer 608 may be from about 0.1 nm to about 100 micrometers. In some embodiments, the thicknesses T₆₀₈ and T₆₀₂ may be equal, and in alternate embodiments, T₆₀₈ may be greater than T₆₀₂ or T₆₀₈ may be greater than T₆₀₂.

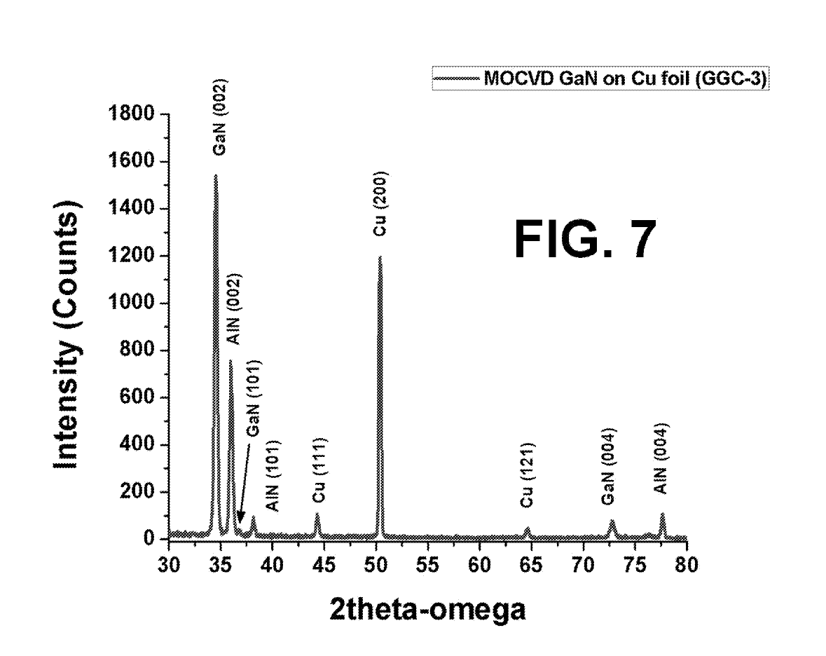

FIG. 7 shows 2theta-omega scan of the film structure 600. Well-oriented GaN peaks (GaN (002), GaN (004) peaks) are observed by the epitaxial growth of GaN 608 on AlN 602. The GaN (002) peak has a higher intensity than the AlN (002) peak, while the GaN (101) peak has a lower intensity that the AlN (101) peak, suggesting that out-of-plane alignment can be further enhanced possibly due to more favorable growth of GaN in c-axis.

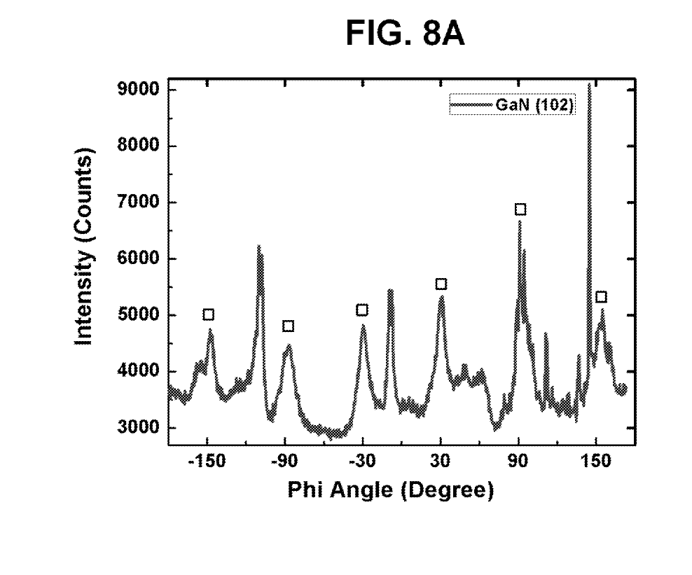

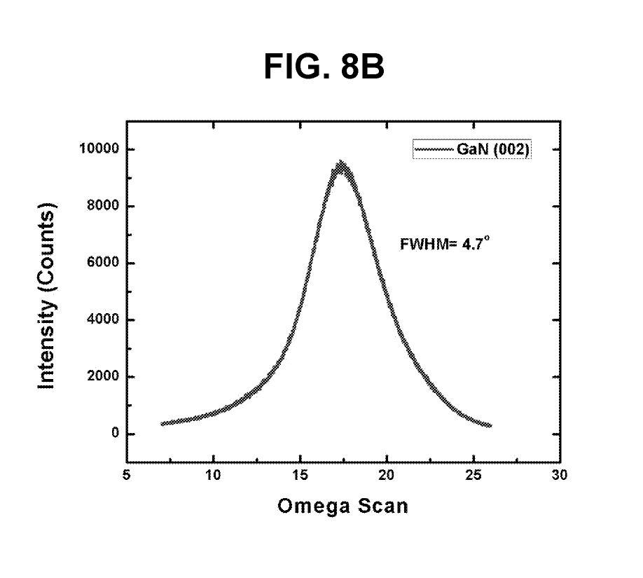

FIG. 8A shows GaN (102) peaks during the rotational scan, suggesting that the GaN film is deposited as a nearly single-crystalline layer, not with random orientations. FIG. 8B shows the rocking curve peak, confirming the single-crystalline nature of GaN with a line width of 4.7° in full-width-at-half-maximum (FWHM). This further confirms that electronic and photonic devices are achievable (may be fabricated) on flexible substrate with variable thicknesses without the use of a transfer process for the graphene. Furthermore, Cu foil offers perfect heat exchange features, which significantly improves device performance.

### Example 2: Direct GaN Growth on 2D Material Formed on Cu or Ni Deposited Film

In another embodiment, using a method applicable to the most of inorganic substrates regardless of their (poly/single/amorphous) crystal structure as long as the substrates can be used in a typical I GaN MOCVD growth temperature (˜1000° C.). As such, the fabrication methods discussed herein can be conducted on rigid and flexible substrates with amorphous, polycrystalline, single-crystalline (with different crystal structure) structure. In this example, a graphene layer is inserted by taking advantage of a catalyst material for graphene growth which makes this method widely applicable for most of inorganic substrates.

In an embodiment, multiple deposition steps are used to fabricate the semiconductor structures and graphene is grown directly on the substrate, in contrast to growing the graphene on another substrate and transferring the graphene to the desired substrate. This example enables direct growth of device-quality GaN on inorganic flexible substrates and Si (100) wafer with and without native amorphous oxide on top. Hence, high-quality semi-conductor layers including AlₓIn_{y}Ga_{1-x-y}N are achievable by taking advantage of device-quality GaN for further device fabrication such as HEMTs, LEDs, lasers, and photodetectors.

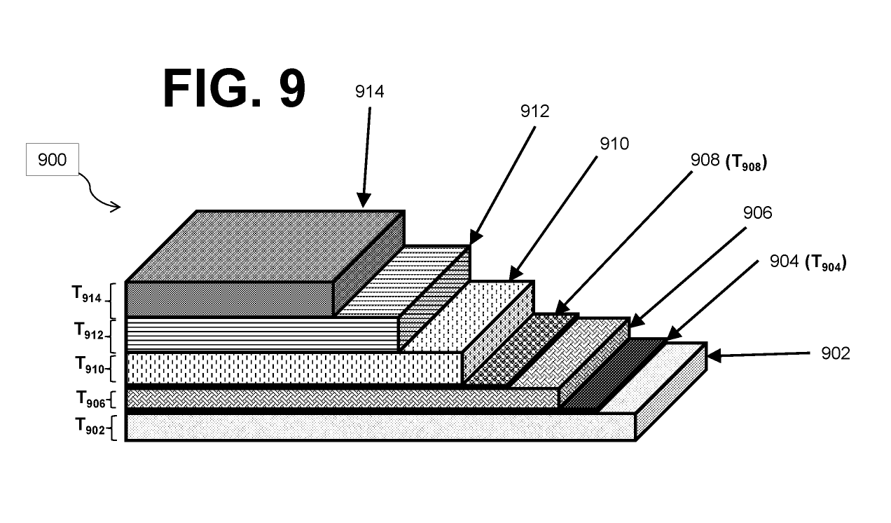

FIG. 9 is a cross-sectional illustration of a structure 900 fabricated according to certain embodiments of the present disclosure. The structure 900 consists of a substrate 902 that may comprise any material having amorphous structure, e.g., SiO₂, etc., a polycrystalline structure, e.g., yttria-stabilized zirconia (YSZ) and Hastelloy flexible tapes, or a single-crystalline structure with a different crystal structure from that of AlₓIn_{y}Ga_{1-x-y}N materials (e.g., a single-crystalline structure other than a wurtzite structure). A catalyst layer 906 such as Cu or Ni is deposited on the substrate 902. A 2D material layer 908 such as graphene or h-BN is grown by CVD method on top of the catalyst layer 906. In an embodiment where a Si (100) wafer is employed as the substrate 902, a native amorphous oxide may or may not be employed in the fabrication. These thicknesses may vary in individual measurement and with respect to the thickness ratio of the individual layers depending upon the embodiment. In one example, a thickness T₉₀₂ of the substrate may be from about 1 nm to about 1 mm, a thickness T₉₀₆ of the catalyst layer 906 may be from about 1 nm to about 1 mm, a thickness T₉₀₈ of the 2D material layer 908 may range from a single monolayer 908 that may be a self-assembled monolayer 908 of about 1 Angstrom to a layer with a thickness T₉₀₈ about 10 nm.

The AlN layer 602 may comprise a thickness from about 0.1 nm to about 100 micrometers, the thickness T₆₀₆ of the flexible substrate 606 may be from about 1 nm to about 1 mm, the graphene layer 604 may comprise a thickness T₆₀₄ that may range from a single monolayer 604 that may be a self-assembled monolayer 604 of about 1 Angstrom to about 10 nm, and the GaN layer 608 may comprise a thickness T₆₀₈ of the GaN layer 608 may be from about 0.1 nm to about 100 micrometers. In some embodiments, the thicknesses T₆₀₈ and T₆₀₂ may be equal, and in alternate embodiments, T₆₀₈ may be greater than T₆₀₂ or T₆₀₈ may be greater than T₆₀₂.

In some embodiments, for example, to improve the adhesion of catalyst layer 906 to substrate 902, an adhesion layer 904 such as titanium (Ti), chromium (Cr), or Ni may be inserted between catalyst layer 906 and substrate 902. The adhesion layer 904 may comprise a thickness T₉₀₄ from about 1 Angstrom to about 1 microns. The catalyst layer 906 can be deposited by different methods including solution electroplating, physical vapor deposition (PVD), e.g. sputtering, or electron beam (e-beam) evaporation. The thickness of the catalyst layer 906 can be in the range of 1 nm to 1 mm. The adhesion layers 904 can also be deposited by similar methods to a thickness of 0.1 nm-1 μm.

In contrast to the bulk nature of the Cu foil substrate discussed in FIG. 1, the deposited catalyst 906 layer, which may be Cu or Ni, may have a porous structure. Thus, use of the catalyst layer 906 may, in some embodiments, enhance film stability during 2D material growth in the next step. The 2D material layer 908 including but not limited to graphene is disposed in contact with the catalyst layer 906 to act as a buffer layer for the AlN layer 910 deposition. In one example, a thickness T₉₁₀ of the AlN layer 910 may be from about 0.1 nm to about 100 micrometers. In an embodiment, a DC magnetron reactive ion sputtering method is employed for the deposition of high-quality c-axis AlN layer 910 on top of 2D material layer 908.

After the epitaxial growth by MOCVD method, a high-quality buffer layer GaN 912 with c-axis preferred orientation is grown using the high-quality deposited c-axis AlN layer 910. Once the GaN buffer layer 912 is grown, for example, to a thickness T₉₁₂ from about 0.1 nm to about 100 micrometers, subsequent layers including AlₓIn_{y}Ga_{1-x-y}N layers (0≤x≤1 and 0≤y≤1) 914 and their heterostructures can be grown epitaxially by MOCVD. The AlₓIn_{y}Ga_{1-x-y}N layers (0≤x≤1 and 0≤y≤1) 914 and their heterostructures can be also be grown on GaN with other embodiments, such as GaN 608 with AlN 602 and other layers shown in 600. In one example, a thickness of the epitaxially grown semiconductor layer or layers 914 may be formed to a thickness T₉₁₄ of 5 nm to about 100 microns. Various thicknesses and compositions may be used for the layers discussed in FIG. 9 depending on the final device structure, and the 2D material(s) employed. The thicknesses T₉₀₄ and T₉₀₈ are indicated next to their respective layers and are measured in the same direction as T₉₀₂, T₉₀₆, T₉₁₀, T₉₁₂, and T₉₁₄.

In one example of another embodiment of the structure 900 in FIG. 9, the graphene layer 908 may be grown (directly deposited) on a substrate 902 of YSZ flexible tape via a CVD method using a Cu deposited film 906. It is appreciated that the layers 902, 904, 906, 908, 910, 912, and 914 are illustrated in FIG. 9 as being of various relative thicknesses. These thicknesses may vary in individual measurement and with respect to the thickness ratio of the individual layers depending upon the embodiment. The thicknesses of AlₓIn_{y}Ga_{1-x-y}N layers (0≤x≤1 and 0≤y≤1) 914, AlN 910, and GaN 912 are varied from tens of nanometers to tens of micrometers.

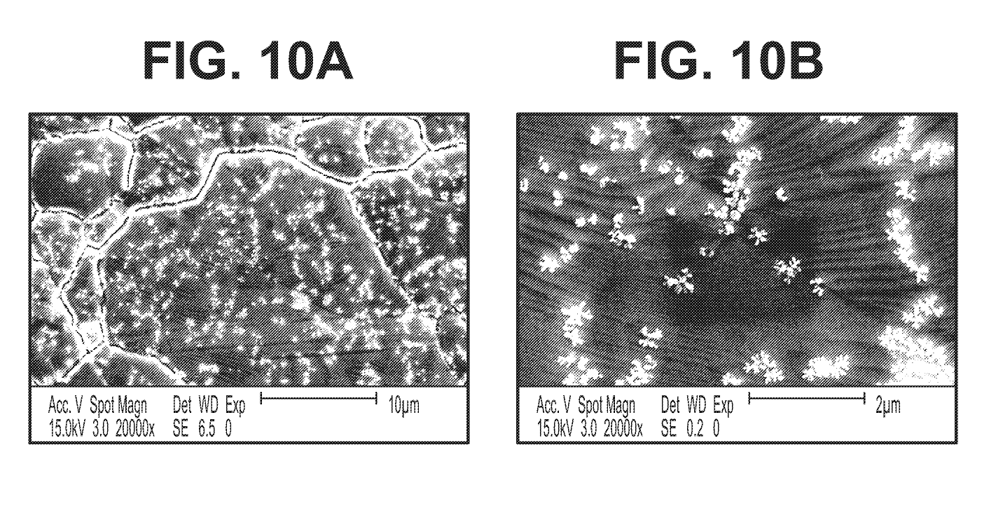

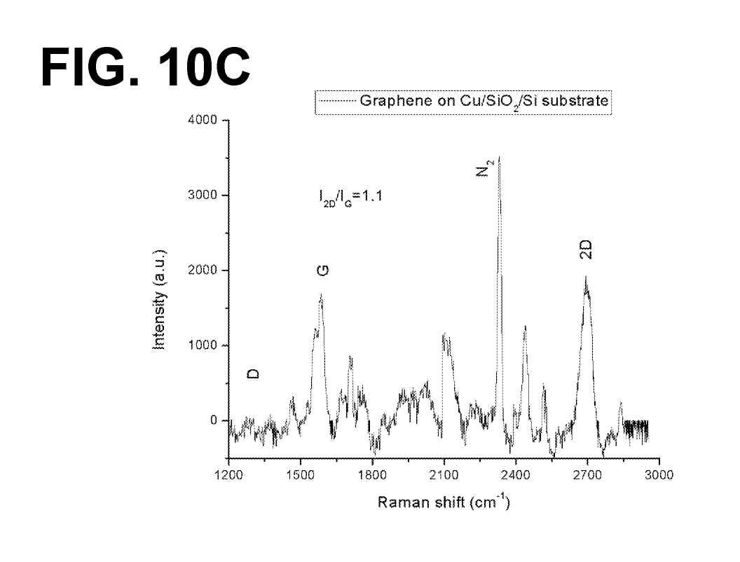

FIGS. 10A and 10B are SEM images of the morphology of graphene layer 908 which was grown on Cu deposited film 906. As discussed in FIG. 9, the catalyst layer 906 is deposited on a Si (100) wafer substrate 902 with 300 nm of SiO₂ thermally grown on top of the wafer substrate 902. Raman spectroscopy confirmed growth of graphene layer 908 on the deposited Cu film 906. FIG. 10C illustrates Raman data for graphene layer 908. In some embodiments, in part based on the ratio intensity 2D peak to G peak (I2D/IG˜1.1), a “layer” or a “deposition” of graphene may refer to a multilayer deposition/growth of graphene (e.g., 1-10 layers) on an Si (100) wafer 902 or other substrate as discussed herein.

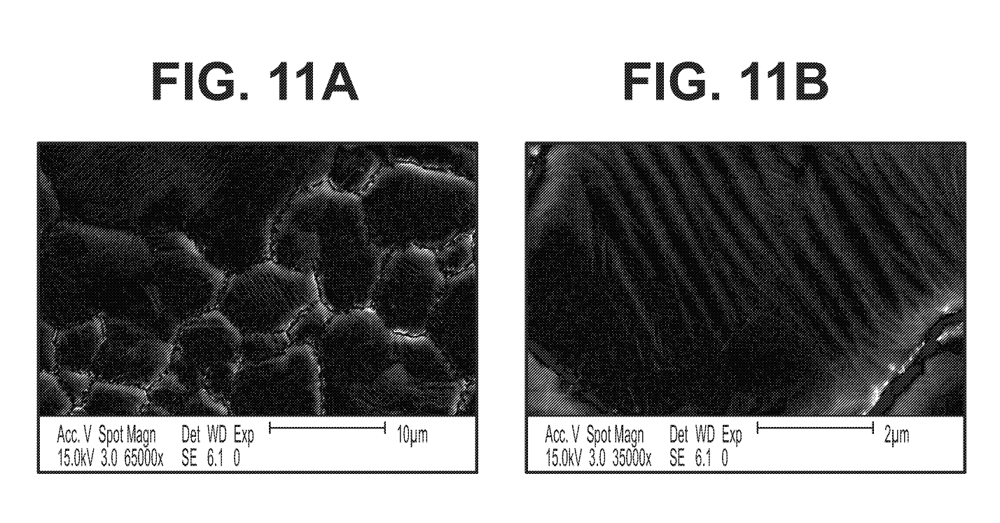

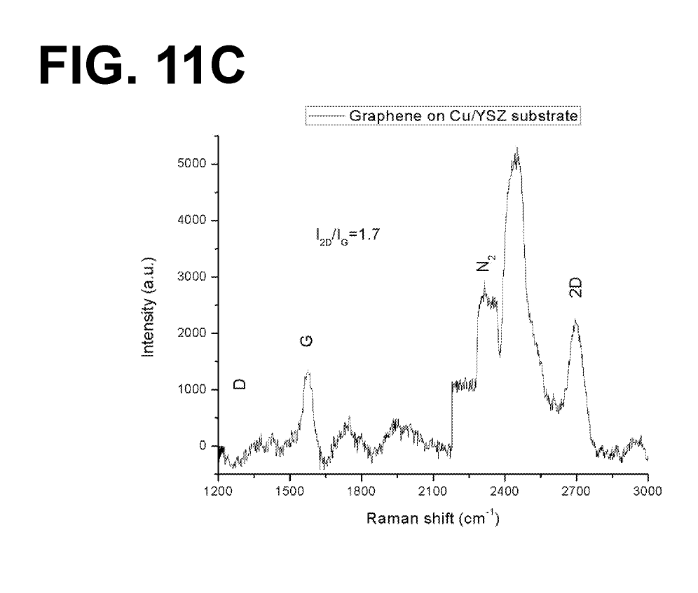

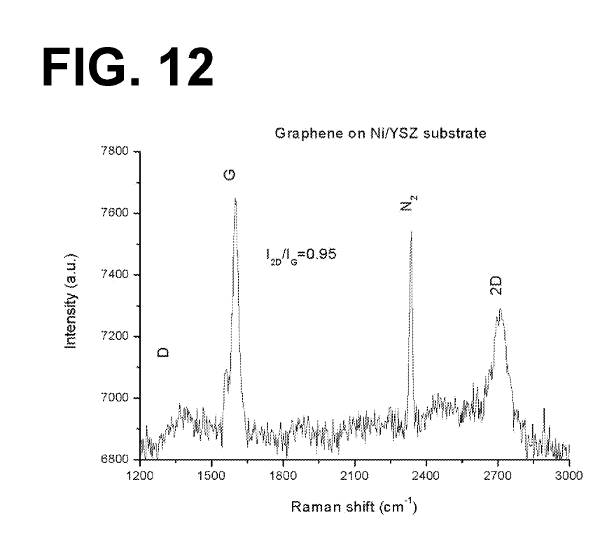

FIGS. 11A and B are SEM images and FIG. 11C is a Raman spectra of a structure similar to that in FIG. 9 where the graphene layer is grown directly on a flexible substrate with a polycrystalline structure, in particular a YSZ flexible tape substrate. FIGS. 11A-11C confirm graphene layer 908 formation (with I2D/IG˜1.7, using two graphene layers to form the layer 908) on top of flexible substrate with polycrystalline structure. FIG. 11C shows Raman data for the graphene layer 908, which is grown a on YSZ flexible substrate 902 using 100 nm Ni film as the catalyst layer 906. Once a high-quality c-axis AlN layer 910 is disposed in contact with the graphene layer 908, a GaN layer 912 growth with high crystalline quality via MOCVD occurs.

Exemplary embodiments have been disclosed. Variations and alternate embodiments that result from combining, integrating, and/or omitting features of the exemplary embodiment(s) are also within the scope of the disclosure. Where numerical ranges or limitations are expressly stated, such express ranges or limitations should be understood to include iterative ranges or limitations of like magnitude falling within the expressly stated ranges or limitations (e.g., from about 1 to about 10 includes, 2, 3, 4, etc.; greater than 0.10 includes 0.11, 0.12, 0.13, etc.). For example, whenever a numerical range with a lower limit, Rₗ, and an upper limit, Rᵤ, is disclosed, any number falling within the range is specifically disclosed. In particular, the following numbers within the range are specifically disclosed: R=Rₗ+k*(Rᵤ−Rₗ), wherein k is a variable ranging from 1 percent to 100 percent with a 1 percent increment, i.e., k is 1 percent, 2 percent, 3 percent, 4 percent, 5 percent, . . . , 50 percent, 51 percent, 52 percent, . . . , 95 percent, 96 percent, 97 percent, 98 percent, 99 percent, or 100 percent. Moreover, any numerical range defined by two R numbers as defined in the above is also specifically disclosed. Use of broader terms such as “comprises,” “includes,” and “having” should be understood to provide support for narrower terms such as “consisting of,” “consisting essentially of,” and “comprised substantially of.” Each and every claim is incorporated into the specification as further disclosure, and the claims are exemplary embodiment(s) of the present invention.

While exemplary embodiments of the invention have been shown and described, modifications thereof can be made by one skilled in the art without departing from the scope or teachings herein. The embodiments described herein are exemplary only and are not limiting. Many variations and modifications of the compositions, systems, apparatus, and methods described herein are possible and are within the scope of the invention. Accordingly, the scope of protection is not limited to the embodiments described herein, but is only limited by the claims that follow, the scope of which shall include all equivalents of the subject matter of the claims. Unless expressly stated otherwise, the steps in a method claim may be performed in any order and with any suitable combination of materials and processing conditions.

1. A method of fabricating a semiconductor device comprising:
forming, via chemical vapor deposition, a 2D material on a substrate, wherein the substrate comprises Si (100), a metallic foil, or an inorganic flexible substrate.

2. The method of claim 1, wherein the 2D material comprises black phosphorous, hexagonal boron nitride (BN), or graphene.

3. The method of claim 1, further comprising forming a c-axis AlN layer on the 2D material layer, wherein the AlN layer comprises a substantially similar in-plane atomic arrangement as the 2D material layer.

4. The method of claim 2, further comprising forming a GaN layer on the AlN layer via chemical vapor deposition (CVD).

5. The method of claim 4, further forming the GaN layer to comprise a wurtzite structure, wherein the AlN layer comprises a wurtzite structure.

6. A method of fabricating a semiconductor structure comprising:
forming a catalyst layer in contact with a substrate;
forming a 2D material layer on the catalyst layer;
forming an AlN layer on the 2D material layer;
forming a buffer layer on the AlN layer; and
forming at least one semiconductor layer on the buffer layer.

7. The method of claim 6, wherein the at least one semiconductor layer comprises GaN, AlₓGa₁₋ₓN, InₓGa₁₋ₓN, or InₓAl_{y}Ga_{1-x-y}N.

8. The method of claim 7, wherein 0≤x≤1 for AlₓGa₁₋ₓN, wherein 0≤x≤1 for InₓGa₁₋ₓN, wherein 0≤x≤1 for InₓAl_{y}Ga_{1-x-y}N, and wherein 0≤y≤1 for InₓAl_{y}Ga_{1-x-y}N.

9. The method of claim 6, further comprising forming an adhesion layer on the substrate prior to forming the catalyst layer, wherein the adhesion layer comprises titanium (Ti), chromium (Cr), or nickel (Ni), or combinations thereof.

10. The method of claim 6, further comprising forming the catalyst by electroplating, physical vapor deposition (PVD), or electron beam (e-beam) evaporation

11. A semiconductor structure comprising:
a substrate;
a layer of 2D material in contact with the substrate;
a first buffer layer on the 2D material layer;
a second buffer layer on the first buffer layer; and
a plurality of semiconductor layers grown epitaxially on the second buffer layer.

12. The structure of claim 11, further comprising a catalyst layer on the substrate layer, the catalyst layer comprises a thickness is from about 1 nm to about 1 mm.

13. The structure of claim 11, further comprising an adhesion layer between the substrate layer and the catalyst layer.

14. The structure of claim 13, wherein the adhesion layer comprises titanium (Ti), chromium (Cr), or nickel (Ni), or combinations thereof.

15. The structure of claim 13, wherein the adhesion layer has a thickness of 0.1 nm-1 μm.

16. The structure of claim 11, wherein the first buffer layer comprises AlN.

17. The structure of claim 11, wherein the second buffer layer comprises GaN.

18. The structure of claim 11, wherein the substrate comprises one of a polycrystalline structure; a single-crystalline structure; and an amorphous structure.

19. The structure of claim 11, wherein the first buffer layer comprises a substantially similar crystallographic structure to a crystallographic structure of the 2D material layer.

20. The structure of claim 11, wherein the first buffer layer comprises a different crystallographic structure than the second buffer layer.
